(19) United States
(12) Patent Application Publication
(10) Pub. No.: US 2026/0062339 A1
(43) Pub. Date: Mar. 5, 2026

(54) GLASS, METHOD FOR PRODUCING GLASS, MEMBER FOR SEMICONDUCTOR PRODUCTION APPARATUS, AND SEMICONDUCTOR PRODUCTION APPARATUS

(71) Applicant: AGC Inc., Tokyo (JP)

(72) Inventors: Kazuki KANEHARA, Tokyo (JP); Tomonori OGAWA, Tokyo (JP)

(73) Assignee: AGC Inc., Tokyo (JP)

(21) Appl. No.: 19/307,146

(22) Filed: Aug. 22, 2025

(30) Foreign Application Priority Data
Aug. 28, 2024 (JP) 2024-146419
Aug. 18, 2025 (JP) 2025-135599

(51) Int. Cl. C03C 3/085; C03C 3/078; C03C 3/089; C03C 3/097; H01J 37/32

(52) U.S. Cl. CPC C03C 3/085; C03C 3/078; C03C 3/089; C03C 3/097; H01J 37/32477

(57) ABSTRACT

A glass including: silicon; magnesium; strontium; and barium, in which the glass has, in mol % based on oxides, a content of SiO₂ of 48.0 mol % or more, a content of Al₂O₃ of 20.0 mol % or less, a content of MgO of 0.1 mol % or more, a content of SrO of 0.1 mol % or more, a content of BaO of 0.1 mol % or more, and a content of R²O of 22.0 mol % or more, provided that R² indicates an alkaline earth metal element, and the glass is substantially free of CaO, substantially free of TiO₂, and substantially free of R¹₂O, provided that R¹ indicates an alkali metal element.

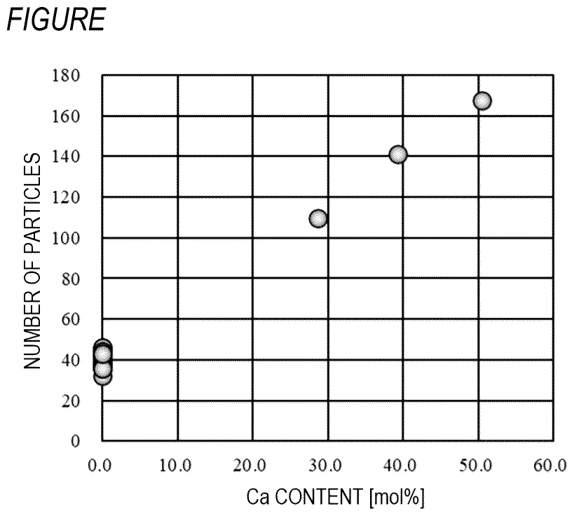

### CROSS-REFERENCE TO RELATED APPLICATIONS

This application is based on and claims priority under 35 USC 119 from Japanese Patent Applications No. 2024-146419 filed on Aug. 28, 2024 and No. 2025-135599 filed on Aug. 18, 2025, the contents of which are incorporated herein by reference.

### TECHNICAL FIELD

The present invention relates to a glass, a method for producing a glass, a member for a semiconductor production apparatus, and a semiconductor production method.

### BACKGROUND ART

During production of a semiconductor device, plasma is used in various semiconductor production apparatuses such as a plasma CVD apparatus and a plasma etching apparatus. A member to be used in the semiconductor production apparatus is often exposed to plasma and gradually worn during the operation of the semiconductor production apparatus. The member that has been worn is replaced with a new member.

In the related art, a quartz glass is often used for a peripheral member in such a semiconductor production apparatus.

As a product produced by the semiconductor production apparatus becomes more 3D-integrated and more complicated, a plasma environment to which the member is to be exposed becomes more severe, and it is frequently necessary to replace the member. Since the semiconductor production apparatus cannot be operated during the replacement of the member, when the replacement frequency of the member increases, production efficiency of the product decreases.

From the viewpoint of further extending the lifetime of the member used in the semiconductor production apparatus, a member having plasma resistance higher than that of the quartz glass is required. Patent Literature 1 describes, as a member for a semiconductor production apparatus, a glass material having a plasma resistance property in which an etching rate is lower than 10 nm/min with respect to mixed plasma of fluorine and argon.
Patent Literature 1: JP2023-508677A

### SUMMARY OF INVENTION

The present inventors have studied a glass having high plasma resistance with reference to the technique described in Patent Literature 1, and have found that the glass has a low etching rate under a plasma environment and is excellent from the viewpoint of etching resistance, but depending on a material contained in the glass, the plasma resistance may be low from the viewpoint of particle precipitation, that is, a large number of particles are precipitated due to a plasma treatment or particles containing a component that may greatly influence a performance of a semiconductor product are precipitated due to a plasma treatment. The particles precipitated in the semiconductor production apparatus under a plasma environment may cause defects in a semiconductor product to be produced.

One aspect of the present disclosure has been made in view of the above points, and an object of the present disclosure is to provide a glass that has excellent etching resistance under a plasma environment, that has a small number of particles precipitated under a plasma environment, and that prevents precipitation of particles containing a component that may greatly influence a performance of a semiconductor product. Another object of the present disclosure is to provide a method for producing the glass and a member for a semiconductor production apparatus related to the glass.

As a result of intensive studies, the present inventors have found that the above objects can be achieved by adopting the following configurations, and have completed the present invention.

That is, solutions to the above problems include the following aspects [1] to [15].
[1]A glass including: silicon; magnesium; strontium; and barium, in which the glass has, in mol % based on oxides, a content of SiO₂ of 48.0 mol % or more, a content of Al₂O₃ of 20.0 mol % or less, a content of MgO of 0.1 mol % or more, a content of SrO of 0.1 mol % or more, a content of BaO of 0.1 mol % or more, and a content of R²O of 22.0 mol % or more, provided that R² indicates an alkaline earth metal element, and the glass is substantially free of CaO, substantially free of TiO₂, and substantially free of R¹₂O, provided that R¹ indicates an alkali metal element.
[2] The glass according to [1], in which the content of Al₂O₃ is 13.5 mol % or less.
[3] The glass according to [1] or [2], which is substantially free of Al₂O₃.
[4] The glass according to any one of [1] to [3], in which the content of BaO is 4.0 mol % to 14.0 mol %.
[5] The glass according to any one of [1] to [4], in which the content of Al₂O₃ is 13.5 mol % or less, and the content of BaO is 4.0 mol % to 14.0 mol %.
[6] The glass according to any one of [1] to [5], which is a glass block.
[7] The glass according to any one of [1] to [6], which is a disk-shaped glass block.
[8] The glass according to any one of [1] to [6], which is an annular glass block.
[9] The glass according to any one of [1] to [8], which is for use as a member for a semiconductor production apparatus to be mounted on a semiconductor production apparatus.
[10] The glass according to [9], in which the member for a semiconductor production apparatus is an edge ring, a shield ring, a focus ring, a shower plate, an electrostatic chuck, a susceptor, an injector, an inspection window, atop plate, or a side wall to be mounted on the semiconductor production apparatus.
[11] A method for producing the glass according to any one of [1] to [10], the method comprising: melting a glass raw material by heating at a melting temperature of 1,400° C. to 1,800° C.; and cooling the obtained molten glass to a cooling stop temperature of 500° C. to 700° C. at a cooling rate of 100° C./min to 1,500° C./min.
[12]A member for a semiconductor production apparatus including: the glass according to any one of [1] to [8].
[13] The member for a semiconductor production apparatus according to [12], which is an edge ring, a shield ring, a focus ring, a shower plate, an electrostatic chuck, a susceptor, an injector, an inspection window, a top plate, or a side wall to be mounted on a semiconductor production apparatus.
[14] A semiconductor production apparatus including: the member for a semiconductor production apparatus according to [12].
[15] A semiconductor production apparatus including: the member for a semiconductor production apparatus according to [13].

According to one aspect of the present disclosure, it is possible to provide a glass that has excellent etching resistance under a plasma environment, that has a small number of particles precipitated under a plasma environment, and that prevents precipitation of particles containing a component that may greatly influence a performance of a semiconductor product. In addition, according to the present invention, it is possible to provide a method for producing the glass and a member for a semiconductor production apparatus related to the glass.

### BRIEF DESCRIPTION OF DRAWINGS

FIGURE is a graph showing a relationship between a Ca content in a glass and the number of particles having a diameter of 100 nm or more measured after a dust generation test.

### DESCRIPTION OF EMBODIMENTS

The terms used in the present specification have the following meanings.

A numerical range represented by using “to” means a range including numerical values described before and after “to” as a lower limit value and an upper limit value.

In a numerical range described in stages in the present specification, an upper limit value or a lower limit value described in a certain numerical range may be replaced with an upper limit value or a lower limit value of another numerical range described in stages. In addition, in a numerical range described in the present specification, an upper limit value or a lower limit value described in a certain numerical range may be replaced with values described in Examples.

In the present specification, a combination of two or more preferred embodiments is a more preferred embodiment.

### [Glass]

A glass according to one embodiment of the present disclosure contains silicon, magnesium, strontium, and barium, in which when an alkali metal element is represented by R¹ and an alkaline earth metal element is represented by R², in mol % based on oxides, a content of SiO₂ is 48.0 mol % or more, a content of Al₂O₃ is 20.0 mol % or less, a content of MgO is 0.1 mol % or more, a content of SrO is 0.1 mol % or more, a content of BaO is 0.1 mol % or more, and a content of R²O is 22.0 mol % or more, and the glass is substantially free of CaO, substantially free of TiO₂, and substantially free of R¹₂O.

Hereinafter, the glass according to the embodiment of the present disclosure is also referred to as “the present glass”.

The present glass has excellent etching resistance under a plasma environment (hereinafter, also simply referred to as “etching resistance”). This is presumed to be because the present glass contains a predetermined amount of the alkaline earth metal element, so that there is a large amount of a component having high resistance to a plasma treatment gas (for example, a fluorine gas) filled in a semiconductor production apparatus during a plasma treatment, and a rate at which a member is worn by the plasma treatment is reduced.

In addition, when the present glass is used for a member for a semiconductor production apparatus, the number of particles precipitated under a plasma environment is reduced. It is presumed that in the case where the glass contains a large amount of Ca, a sublimation point of CaF₂, which is a reaction product of Ca and atoms of the plasma treatment gas such as fluorine is too high, so that the particles of CaF₂ do not volatilize under a plasma environment and remain in the semiconductor production apparatus as particles. With respect to this, it is presumed that since the present glass is substantially free of CaO, the precipitation of particles under a plasma environment, in particular, the precipitation of particles having a diameter of 100 nm or more, which can particularly influence wiring of a semiconductor product, is prevented.

Hereinafter, a performance of reducing the number of particles precipitated when exposed to a plasma environment is also referred to as “dust generation resistance”.

Further, when the present glass is used for a member for a semiconductor production apparatus, it is possible to prevent the precipitation of particles containing a component (hereinafter, also referred to as a “component X”) that may greatly influence the performance of the semiconductor product. Examples of such a component X include Ti and an alkali metal element represented by Na. The reason why the precipitation of the particles containing the component X can be prevented is presumed that the present glass is substantially free of TiO₂ and substantially free of R¹₂O that is an oxide of an alkali metal element.

In the semiconductor production apparatus, a member used in an environment exposed to plasma is, for example, a member made of a quartz glass.

However, the quartz glass has insufficient etching resistance. With respect to this, the present glass has excellent etching resistance, can reduce the number of particles precipitated under a plasma environment, and can prevent the precipitation of particles containing the component X.

Hereinafter, the present glass is described in detail.

First, a composition of the present glass (glass composition) is described below. That is, contents (in mol % based on oxides) of elements that may be contained in the present glass is described.

### <Si>

The present glass contains silicon (Si).

### <<SiO₂>>

For the reason that chemical durability of the present glass is superior, the content of SiO₂ is 48.0 mol % or more, preferably 50.0 mol % or more, more preferably 51.0 mol % or more, still more preferably 52.0 mol % or more, even more preferably 53.0 mol % or more, particularly preferably 55.0 mol % or more, and most preferably 58.0 mol % or more.

For the reason of being capable of increasing the content of a component that improves the etching resistance of the present glass, the content of SiO₂ is preferably 78.0 mol % or less, more preferably 75.0 mol % or less, still more preferably 70.0 mol % or less, even more preferably 68.0 mol % or less, particularly preferably 66.0 mol % or less, and most preferably 65.0 mol % or less.

### <R²>

Examples of the alkaline earth metal element (R²) include beryllium (Be), magnesium (Mg), calcium (Ca), strontium (Sr), and barium (Ba).

The present glass contains Mg, Sr, and Ba as essential elements.

On the other hand, the present glass is substantially free of CaO.

The present glass may contain one or both of Be and Ra.

The alkaline earth metal element (R²) contained in the present glass is preferably substantially Mg, Sr, and Ba.

### <<<R²O>

For the reason that etching resistance of the present glass is superior, the content of R²O is 22.0 mol % or more, preferably 24.0 mol % or more, more preferably 27.0 mol % or more, still more preferably 30.0 mol % or more, even more preferably 32.0 mol % or more, particularly preferably 34.0 mol % or more, and most preferably 35.0 mol % or more.

For the reason of being capable of preventing the precipitation of a crystal due to devitrification in the production of the present glass, the content of R²O is preferably 52.0 mol % or less, more preferably 50.0 mol % or less, still more preferably 47.5 mol % or less, even more preferably 45.0 mol % or less, particularly preferably 44.0 mol % or less, more particularly preferably 42.0 mol % or less, and most preferably 40.0 mol %.

### <<MgO>>

For the reason that etching resistance of the present glass is superior, the content of MgO is 0.1 mol % or more, preferably 1.0 mol % or more, more preferably 2.0 mol % or more, still more preferably 3.0 mol % or more, even more preferably 4.0 mol % or more, particularly preferably 5.0 mol % or more, and most preferably 8.0 mol % or more.

For the reason of being capable of preventing the precipitation of a crystal due to devitrification in the production of the present glass, the content of MgO is preferably 50.0 mol % or less, more preferably 40.0 mol % or less, still more preferably 35.0 mol % or less, even more preferably 30.0 mol % or less, particularly preferably 25.0 mol % or less, more particularly preferably 20.0 mol % or less, and most preferably 18.0 mol % or less.

### <<SrO>>

For the reason that etching resistance of the present glass is superior, the content of SrO is 0.1 mol % or more, preferably 1.0 mol % or more, more preferably 2.0 mol % or more, still more preferably 3.0 mol % or more, even more preferably 4.0 mol % or more, particularly preferably 5.0 mol % or more, and most preferably 8.0 mol % or more.

For the reason of being capable of preventing the precipitation of a crystal due to devitrification in the production of the present glass, the content of SrO is preferably 50.0 mol % or less, more preferably 40.0 mol % or less, still more preferably 35.0 mol % or less, even more preferably 30.0 mol % or less, particularly preferably 25.0 mol % or less, more particularly preferably 20.0 mol % or less, and most preferably 18.0 mol % or less.

### <<BaO>>

For the reason that etching resistance of the present glass is superior, the content of BaO is 0.1 mol % or more, preferably 1.0 mol % or more, more preferably 2.0 mol % or more, still more preferably 3.0 mol % or more, even more preferably 4.0 mol % or more, particularly preferably 5.0 mol % or more, more particularly preferably 8.0 mol % or more, and most preferably 9.0 mol % or more.

For the reason of being capable of preventing the precipitation of a crystal due to devitrification in the production of the present glass, the content of BaO is preferably 50.0 mol % or less, more preferably 40.0 mol % or less, still more preferably 35.0 mol % or less, even more preferably 30.0 mol % or less, particularly preferably 25.0 mol % or less, very preferably 20.0 mol % or less, more particularly preferably 18.0 mol % or less, and most preferably 14.0 mol % or less.

### <<SrO/BaO>>

For the reason that etching resistance of the present glass is superior, a ratio of SrO/BaO is preferably 3.0 or less, more preferably 2.5 or less, still more preferably 2.0 or less, even more preferably 1.5 or less, particularly preferably 1.25 or less, and most preferably 1.0 or less.

For the reason of being capable of preventing the precipitation of a crystal due to devitrification in the production of the present glass, the ratio of SrO/BaO is preferably 0.1 or more, more preferably 0.2 or more, still more preferably 0.3 or more, even more preferably 0.35 or more, particularly preferably 0.4 or more, very preferably 0.45 or more, and most preferably 0.5 or more.

### <<CaO>>

For the reason that dust generation resistance of the present glass is superior, the present glass is substantially free of CaO. Here, “substantially free of CaO” means that the content of CaO is less than 0.1 mass %. The content of CaO is preferably 0.08 mass % or less, more preferably 0.05 mass % or less, and still more preferably 0.03 mass % or less.

The content of CaO may be zero.

### <Al>

The present glass may contain aluminum (Al).

<<Al₂O₃>>

For the reason that etching resistance of the present glass is superior, the content of Al₂O₃ is 20.0 mol % or less, preferably 17.0 mol % or less, more preferably 15.0 mol % or less, still more preferably 13.5 mol % or less, even more preferably 10.0 mol % or less, particularly preferably 8 mol % or less, more particularly preferably 6 mol % or less, and most preferably 5 mol % or less.

Among them, the present glass is still most preferably substantially free of Al₂O₃. Here, “substantially free of Al₂O₃” means that the content of Al₂O₃ is less than 0.1 mass %. The content of Al₂O₃ is preferably 0.08 mass % or less, more preferably 0.05 mass % or less, and still more preferably 0.03 mass % or less.

A lower limit of the content of Al₂O₃ is preferably zero.

### <Ti (TiO₂)>

For the reason of being capable of preventing the precipitation of particles containing the component X when used for the member for a semiconductor production apparatus, the present glass is substantially free of TiO₂. Here, “substantially free of TiO₂” means that the content of TiO₂ is less than 0.1 mass %.

The content of TiO₂ may be zero.

<R¹ (R¹₂O)>

For the reason of being capable of preventing the precipitation of particles containing the component X when used for the member for a semiconductor production apparatus, the present glass is substantially free of an oxide (R¹₂O) of the alkali metal element (R¹). Here, “substantially free of R¹₂O” means that the content of R¹₂O is less than 0.1 mass %.

Examples of the alkali metal element (R¹) include lithium (Li), sodium (Na), potassium (K), rubidium (Rb), cesium (Cs), and francium (Fr).

### <B, P, and Ge>

The present glass may further contain at least one element selected from the group consisting of boron (B), phosphorus (P), and germanium (Ge).

<<B₂O₃>>

For the reason that etching resistance of the present glass is superior, a content of B₂O₃ is preferably 25.0 mol % or less, more preferably 20.0 mol % or less, still more preferably 15.0 mol % or less, even more preferably 13.0 mol % or less, particularly preferably 10.0 mol % or less, more particularly preferably 9.0 mol % or less, very preferably 6.0 mol % or less, most preferably 5.0 mol % or less, and still most preferably 1.0 mol % or less.

A lower limit of the content of B₂O₃ is preferably zero.

<<P₂O₅>>

For the reason that etching resistance of the present glass is superior, a content of P₂O₅ is preferably 9.0 mol % or less, more preferably 7.0 mol % or less, still more preferably 5.5 mol % or less, even more preferably 4.0 mol % or less, still even more preferably 3.0 mol % or less, particularly preferably 2.0 mol % or less, more particularly preferably 1.5 mol % or less, and most preferably 1.0 mol % or less.

A lower limit of the content of P₂O₅ is preferably zero.

### <<GeO₂>>

For the reason that etching resistance of the present glass is superior, a content of GeO₂ is preferably 9.0 mol % or less, more preferably 5.5 mol % or less, still more preferably 4.0 mol % or less, even more preferably 2.0 mol % or less, and particularly preferably 1.0 mol % or less.

A lower limit of the content of GeO₂ is preferably zero.

### <Impurity Element>

For the reason that etching resistance of the present glass is superior, a content of an impurity element in terms of oxides is preferably 15.0 mol % or less, more preferably 10.0 mol % or less, still more preferably 7.5 mol % or less, even more preferably 5.0 mol % or less, particularly preferably 1.0 mol % or less, very preferably 0.5 mol % or less, and most preferably 0.05 mol % or less.

A lower limit of the content of the impurity element in terms of oxides is preferably zero.

The impurity element is a metal element excluding silicon (Si), the alkaline earth metal element (R²), aluminum (Al), titanium (Ti), the alkali metal element (R¹), boron (B), phosphorus (P), and germanium (Ge).

Examples of the impurity element include Cu, Fe, Ni, Cr, Sn, Co, V, Bi, Se, Ce, Er, Nd, Y, Ga, In, Zr, Mn, Zn, and Ta.

A content of Cu in terms of oxides specifically means a content of CuO.

A content of Fe in terms of oxides specifically means a content of Fe₂O₃.

A content of Ni in terms of oxides specifically means a content of NiO.

A content of Cr in terms of oxides specifically means a content of Cr₂O₃.

A content of Sn in terms of oxides specifically means a content of SnO₂.

A content of Co in terms of oxides specifically means a content of CO₃O₄.

A content of V in terms of oxides specifically means a content of V₂O₅.

A content of Bi in terms of oxides specifically means a content of Bi₂O₃.

A content of Se in terms of oxides specifically means a content of SeO₂.

A content of Ce in terms of oxides specifically means a content of CeO₂.

A content of Er in terms of oxides specifically means a content of Er₂O₃.

A content of Nd in terms of oxides specifically means a content of Nd₂O₃.

A content of Y in terms of oxides specifically means a content of Y₂O₃.

A content of Ga in terms of oxides specifically means a content of Ga₂O₃.

A content of In in terms of oxides specifically means a content of In₂O₃.

A content of Zr in terms of oxides specifically means a content of ZrO₂.

A content of Mn in terms of oxides specifically means a content of MnO₂.

A content of Zn in terms of oxides specifically means a content of ZnO.

A content of Ta in terms of oxides specifically means a content of Ta₂O₅.

An example of a preferred embodiment of the present glass is a glass containing silicon, magnesium, strontium, and barium, in which when an alkali metal element is represented by R¹ and an alkaline earth metal element is represented by R², in mol % based on oxides, the content of SiO₂ is 48.0 mol % or more, the content of MgO is 0.1 mol % or more, the content of SrO is 0.1 mol % or more, the content of BaO is 0.1 mol % or more, and the content of R²O is 22.0 mol % or more, and the glass is substantially free of Al₂O₃, substantially free of CaO, substantially free of TiO₂, and substantially free of R¹₂O.

Another example of a preferred embodiment of the present glass is a glass containing silicon, magnesium, strontium, and barium, in which when an alkali metal element is represented by R¹ and an alkaline earth metal element is represented by R², in mol % based on oxides, the content of SiO₂ is 48.0 mol % or more, the content of Al₂O₃ is 13.5 mol % or less, the content of MgO is 0.1 mol % or more, the content of SrO is 0.1 mol % or more, the content of BaO is 4.0 mol % to 14.0 mol %, and the content of R²O is 22.0 mol % or more, and the glass is substantially free of CaO, substantially free of TiO₂, and substantially free of R¹₂O.

In each of the above preferred embodiments, an embodiment in which the content of each component is in the above preferable range is a more preferred embodiment.

The content (in mol % based on oxides) of each of the above elements (excluding Si) in the glass is measured using an X-ray fluorescence device (XRF) (“ZSX100e” manufactured by Rigaku Corporation). That is, an X-ray intensity of each element on a surface of the glass is measured and quantitatively analyzed to thereby obtain the content of each element.

The content of SiO₂ in the glass is determined as follows.

First, a powder sample is taken from the glass (for example, a center portion of a glass block to be described later) by polishing, and a total oxygen amount Z1 in the glass is determined by an infrared absorption method using an oxygen/hydrogen analyzer (ROH-600 manufactured by LECO Corporation).

An oxygen amount Z3 is calculated by subtracting an oxygen amount Z2 bound to the elements (excluding Si) contained in the glass in the stoichiometric composition from the total oxygen amount Z1 in the glass (oxygen amount Z3=total oxygen amount Z1−oxygen amount Z2).

Assuming that the entire oxygen amount Z3 has been used for bonding with silicon atoms, the oxygen amount Z3 is converted to an amount of SiO₂. The amount of SiO₂ obtained in this manner is set as the content of SiO₂ in the glass.

An etching rate of the present glass under a plasma environment is preferably 1,000 nm/h or less. The etching rate is more preferably 900 nm/h or less, still more preferably 700 nm/h or less, particularly preferably 600 nm/h or less, very preferably 500 nm/h or less, and most preferably 300 nm/h or less. The etching rate of the present glass under a plasma environment may be 0 nm/h.

The etching rate under a plasma environment in the present specification is measured by the method described in Examples to be described later.

The number of particles having a diameter of 100 nm or more precipitated in the present glass under a plasma environment is preferably 100 or less. The number of particles is more preferably 80 or less, still more preferably 50 or less, and particularly preferably 40 or less. The number of particles precipitated in the present glass under a plasma environment may be 0.

The number of particles precipitated under a plasma environment in the present specification is measured by the measurement method described in Examples to be described later.

### <Glass Block>

The present glass is preferably a glass block.

The “glass block” means that the glass is a lump, and is a concept that does not include at least any of a glass frit, a glass powder, and a glass fiber. The glass block may have any shape.

### <<Shape of Glass Block>>

Examples of the shape of the glass block include a plate shape (for example, a disk shape and a flat plate shape), a spherical shape, an elongated spheroidal shape, a columnar shape, or a rectangular parallelepiped shape.

The glass block may have a hole. Examples of the shape of the glass block having a hole include an annular shape (for example, a ring shape or a doughnut shape) and a tubular shape. The glass block may have a plurality of holes.

The shape of the glass block is appropriately selected according to an application. For example, in the case of being used as a focus ring or an edge ring to be described later, an annular glass block is adopted.

In the case where the present glass has a plate shape, an area of at least one surface (for example, a main surface) of the present glass is preferably 25 mm² or more, more preferably 100 mm² or more, still more preferably 500 mm² or more, even more preferably 1,000 mm² or more, particularly preferably 5,000 mm² or more, more particularly preferably 10,000 mm² or more, very preferably 40,000 mm² or more, and most preferably 90,000 mm² or more.

In the case where the present glass has a plate shape, a thickness of the present glass (thickness of the thinnest portion) is preferably 0.3 mm or more, more preferably 0.5 mm or more, still more preferably 1 mm or more, even more preferably 3 mm or more, particularly preferably 6 mm or more, more particularly preferably 10 mm or more, very preferably 15 mm or more, and most preferably 20 mm or more.

On the other hand, for the reason that crystallization of the present glass is prevented and of transparency is superior, the thickness of the present glass is preferably 500 mm or less, more preferably 100 mm or less, still more preferably 80 mm or less, even more preferably 60 mm or less, particularly preferably 50 mm or less, very preferably 40 mm or less, and most preferably 30 mm or less.

### <Application>

The present glass can be used, for example, as a member for a semiconductor production apparatus, and in particular, can be suitably used as a member to be mounted on a plasma etching apparatus or a plasma CVD apparatus. However, the application of the present glass is not limited thereto.

Another embodiment of the present invention is a member for a semiconductor production apparatus containing the present glass.

Examples of the member to be mounted on a semiconductor production apparatus (such as a plasma etching apparatus, and a plasma CVD apparatus) include a shield ring, a focus ring, an edge ring, a shower plate, an electrostatic chuck, a susceptor, an injector, an inspection window, a top plate, a side wall, a microwave introduction tube, a lift pin, various nozzles, a window material, and a protective cover for an in-chamber sensor. The present glass can be suitably used particularly as a focus ring, a shower plate, an electrostatic chuck, a susceptor, an injector, an inspection window, a top plate, or a side wall.

### [Method for Producing Glass]

Next, a method for producing the present glass (hereinafter, also referred to as “the present production method”) is described. In the present production method, generally, glass raw materials are melted by heating, and the obtained molten glass is molded, followed by annealing.

More specifically, first, various glass raw materials are weighed and mixed such that the composition of the glass to be obtained is the above glass composition.

Next, the mixed glass raw materials are heated and melted using a glass melting furnace or the like. At this time, defoaming, homogenization, and the like are appropriately performed on the molten material by a known method. In this manner, a molten glass is obtained.

Thereafter, the obtained molten glass is molded into a desired shape, followed by cooling. Examples of a molding method include a float method, a press method, a fusion method, and a down-draw method. After the obtained molten glass is molded into a temporary shape and then cooled, the obtained temporarily shaped body may be subjected to processing such as cutting. In this manner, a glass (glass block) having a desired shape is obtained.

If necessary, processing such as grinding and polishing may be performed on the obtained glass.

A temperature (hereinafter, also referred to as a “melting temperature”) at which the glass raw materials are heated and melted is preferably 1,400° C. to 1,800° C., more preferably 1,450° C. to 1,750° C., and still more preferably 1,500° C. to 1,700° C., for the reason of excellent production properties.

A time (hereinafter also referred to as a “melting time”) for heating and melting the glass raw materials is preferably 24 hours or shorter, more preferably 12 hours or shorter, still more preferably 10 hours or shorter, even more preferably 8 hours or shorter, particularly preferably 6 hours or shorter, and most preferably 4 hours or shorter, from the viewpoint of a refining property. The melting time is preferably 2 hours or longer, and more preferably 3 hours or longer, from the viewpoint of reducing unmelted raw materials and bubbles in the glass.

A cooling rate in cooling the molten glass is preferably 50° C./min or more, more preferably 60° C./min or more, still more preferably 70° C./min or more, particularly preferably 80° C./min or more, and most preferably 100° C./min or more from the viewpoint of a crystal acceleration property, and is preferably 3,000° C./min or less, more preferably 2,000° C./min or less, and still more preferably 1,500° C./min or less from the viewpoint of producing the glass without breaking.

The cooling of the molten glass at the above cooling rate is stopped when the glass reaches a predetermined temperature (hereinafter also referred to as a “cooling stop temperature”). The cooling stop temperature is preferably 0° C. to 1,000° C., more preferably 300° C. to 900° C., still more preferably 400° C. to 800° C., and particularly preferably 500° C. to 700° C. from the viewpoint of not leaving a strain in the glass.

The glass block cooled to the cooling stop temperature is naturally cooled or annealed to an ambient temperature (for example, 25° C.) to thereby obtain the present glass.

An example of a preferred embodiment of the present production method is a method in which a glass raw material is melted by heating at a melting temperature of 1,400° C. to 1,800° C., and the obtained molten glass is cooled to a cooling stop temperature of 500° C. to 700° C. at a cooling rate of 100° C./min to 1,500° C./min.

### EXAMPLES

Hereinafter, the present invention is specifically described with reference to Examples. However, the present invention is not limited to Examples described below.

Hereinafter, Examples 1 to 22 are Working Examples, and Examples 23 to 29 are Comparative Examples.

### Examples 1 to 29

A glass block in each example was obtained as follows.

Glass raw materials were weighed and mixed such that the glass blocks to be obtained contained compositions (in mol % based on oxides) shown in the following Tables 1 to 4 and were each 400 g.

The mixed glass raw materials were charged into a platinum crucible, which was placed in an electric furnace, and melting was performed by heating at a temperature of 1,500° C. to 1,700° C. for about 3 hours, followed by defoaming and homogenization to thereby obtain a molten glass.

A part of the obtained molten glass was poured into a metal mold and cooled at a cooling rate of 100° C./min to 1,500° C./min until the temperature reached 500° C. to 700° C., which was about 50° C. higher than the glass transition point. The glass in the metal mold was held at 500° C. to 700° C. for 1 hour and then cooled to room temperature at a rate of 1° C./min to obtain a plate-shaped glass block (area of main surface: 10,000 mm², thickness: 10 mm).

### <Content of Each Element>

In the glass block in each example, the content (in mol % based on oxides) of each element was determined by the method described above. The results are shown in the following Tables 1 to 4.

### <Etching Resistance Test (Etching Rate)>

The glass block in each example was subjected to plasma etching to evaluate the etching resistance.

More specifically, the prepared glass block was cut into a test piece having a size of 20 mm×20 mm×2 mm, and the surface having a size of 20 mm×20 mm of the test piece was polished with cerium oxide so as to be a mirror surface. Next, half of the polished surface was covered with a polyimide tape (“P-222” manufactured by Nitto Denko Corporation) having a total thickness of 100 m to prepare a sample for an etching resistance test.

Thereafter, the sample was placed on a stage of a plasma etching apparatus (“EXAM” manufactured by SHINKO SEIKI CO., LTD.), and plasma etching was performed using a mixed gas of CF₄/O₂/Ar. Regarding the plasma etching, the output was 550 W, the pressure was 3 Pa, and the etching time was 60 minutes.

After the plasma etching, the polyimide tape was peeled off from the surface of the sample, and a height of a step formed between the covered surface and the exposed surface was measured using a stylus profilometer Dektak-XT (manufactured by ULVAC, Inc.). The measurement was performed at three points, and the etching rate (unit: nm/h) was obtained based on an arithmetic mean value of the measured values at the three points and the etching time.

The results are shown in the following tables. As the etching rate is smaller, it can be evaluated that the etching resistance is excellent.

### <Dust Generation Test>

The glass block in each example was cut to prepare a sample having a size of 20 mm×20 mm×2 mm and having a glass surface of 20 mm×20 mm.

Next, a disk-shaped silicon wafer having a diameter of 6 inches (150 mm) was placed on a stage of a plasma etching apparatus (“EXAM” manufactured by SHINKO SEIKI CO., LTD.), and the sample was placed at a center position of a surface of the silicon wafer.

Thereafter, plasma etching was performed on the silicon wafer on which the sample was placed using a mixed gas of CF₄/O₂/Ar. Regarding the plasma etching, the output was 550 W, the pressure was 3 Pa, and the etching time was 60 minutes.

After the plasma etching, the silicon wafer and the sample were taken out from the plasma etching apparatus, and then particles having a diameter of 100 nm or more adhering to the surface of the silicon wafer were detected using a particle inspection apparatus (“LODAS” manufactured by LAZIN Co., LTD.). The particles were imaged using a camera included in the particle inspection apparatus, a major axis of the particles displayed in the obtained image was measured, and the measured major axis was used as the diameter of the particles.

Of the circular surface of the silicon wafer, an outer peripheral portion having a width of 3 mm from an outer periphery of the circle and a center portion having a diameter of 40 mm from the center of the circle (including a region where the sample was placed) were excluded from the count, and the number of particles detected on the surface other than the outer peripheral portion and the center portion was counted. The measurement results of the number of particles in each example are shown in the following tables. As the number of particles is smaller, it can be evaluated that dust generation resistance is excellent.

### <Particle Composition>

The particles obtained in the dust generation test were collected and subjected to elemental analysis. More specifically, the content of the element contained in the particles was measured using an X-ray fluorescence analyzer (XRF) (“ZSX100e” manufactured by Rigaku Corporation). That is, the X-ray intensity of each element on the surface of the particles was measured and quantitatively analyzed to thereby obtain the content of each element. The content of each element in mol % based on oxides is shown in the following tables. The unit of the numerical value shown in the column of “SrO/BaO” is dimensionless. For each example, as a result of the elemental analysis on the particles, in the case where at least one of the alkali metal element and Ti was detected, “C” was recorded in the column of “particle composition”, in the case where neither the alkali metal element nor Ti was detected and Al was detected, “B” was recorded in the column of “particle composition”, and in the case where none of the alkali metal element, Ti, and Al was detected, “A” was recorded in the column of “particle composition” in the tables.

Since Ti and the alkali metal element represented by Na correspond to the component X that may greatly influence the performance of a semiconductor product, when the evaluation of the particle composition is “A” or “B”, it can be evaluated that the properties as a member for a semiconductor production apparatus to be used under a plasma environment are excellent. In addition, since Al may slightly influence the performance of the semiconductor product depending on a semiconductor material, when the evaluation of the particle composition is “A”, it can be evaluated that the properties as the member for a semiconductor production apparatus to be used under a plasma environment are more excellent.

TABLE 1

| | Example | Example | Example | Example | Example | Example | Example |
|---|---|---|---|---|---|---|---|
| | 1 | 2 | 3 | 4 | 5 | 6 | 7 |
| SiO₂ | 65.9 | 62.5 | 57.5 | 50.0 | 70.0 | 55.0 | 60.0 |
| Al₂O₃ | 6.0 | 0.0 | 0.0 | 0.0 | 0.0 | 0.0 | 0.0 |
| B₂O₃ | 0.0 | 0.0 | 0.0 | 0.0 | 0.0 | 0.0 | 4.0 |
| P₂O₅ | 0.0 | 0.0 | 0.0 | 0.0 | 0.0 | 0.0 | 0.0 |
| GeO₂ | 0.0 | 0.0 | 0.0 | 0.0 | 0.0 | 0.0 | 0.0 |
| MgO | 5.2 | 14.5 | 19.5 | 15.0 | 5.0 | 19.0 | 9.8 |
| CaO | 0.0 | 0.0 | 0.0 | 0.0 | 0.0 | 0.0 | 0.0 |
| SrO | 9.0 | 12.0 | 12.0 | 15.0 | 8.0 | 14.0 | 12.0 |
| BaO | 13.9 | 11.0 | 11.0 | 20.0 | 17.0 | 12.0 | 14.2 |
| Na₂O | 0.0 | 0.0 | 0.0 | 0.0 | 0.0 | 0.0 | 0.0 |
| TiO₂ | 0.0 | 0.0 | 0.0 | 0.0 | 0.0 | 0.0 | 0.0 |
| R²O | 28.1 | 37.5 | 42.5 | 50.0 | 30.0 | 45.0 | 36.0 |
| R¹₂O | 0.0 | 0.0 | 0.0 | 0.0 | 0.0 | 0.0 | 0.0 |
| SrO/BaO | 0.6 | 1.1 | 1.1 | 0.8 | 0.5 | 1.2 | 0.8 |
| Etching rate | 554 | 280 | 208 | 119 | 510 | 191 | 361 |
| [nm/h] | | | | | | | |
| Number of | 32 | 39 | 37 | 45 | 42 | 38 | 41 |
| particles | | | | | | | |
| Particle | A | A | A | A | A | A | A |
| composition | | | | | | | |

TABLE 2

| | Example | Example | Example | Example | Example | Example | Example |
|---|---|---|---|---|---|---|---|
| | 8 | 9 | 10 | 11 | 12 | 13 | 14 |
| SiO₂ | 60.0 | 60.0 | 65.0 | 50.0 | 54.5 | 57.0 | 64.0 |
| Al₂O₃ | 0.0 | 0.0 | 0.0 | 11.0 | 4.5 | 0.0 | 0.0 |
| B₂O₃ | 0.0 | 0.0 | 0.0 | 0.0 | 0.0 | 0.0 | 0.0 |
| P₂O₅ | 4.0 | 0.0 | 0.0 | 0.0 | 0.0 | 0.0 | 0.0 |
| GeO₂ | 0.0 | 4.0 | 0.0 | 0.0 | 0.0 | 0.0 | 0.0 |
| MgO | 9.8 | 9.8 | 12.0 | 12.0 | 10.0 | 12.0 | 15.0 |
| CaO | 0.0 | 0.0 | 0.0 | 0.0 | 0.0 | 0.0 | 0.0 |
| SrO | 12.0 | 12.0 | 12.0 | 10.0 | 11.0 | 11.0 | 14.0 |
| BaO | 14.2 | 14.2 | 11.0 | 17.0 | 20.0 | 20.0 | 7.0 |
| Na₂O | 0.0 | 0.0 | 0.0 | 0.0 | 0.0 | 0.0 | 0.0 |
| TiO₂ | 0.0 | 0.0 | 0.0 | 0.0 | 0.0 | 0.0 | 0.0 |
| R²O | 36.0 | 36.0 | 35.0 | 39.0 | 41.0 | 43.0 | 36.0 |
| R¹₂O | 0.0 | 0.0 | 0.0 | 0.0 | 0.0 | 0.0 | 0.0 |
| SrO/BaO | 0.8 | 0.8 | 1.1 | 0.6 | 0.6 | 0.6 | 2.0 |
| Etching rate | 301 | 314 | 394 | 385 | 346 | 178 | 318 |
| [nm/h] | | | | | | | |
| Number of | 43 | 40 | 39 | 46 | 46 | 37 | 44 |
| particles | | | | | | | |
| Particle | A | A | A | A | A | A | A |
| composition | | | | | | | |

TABLE 3

| | Example | Example | Example | Example | Example | Example | Example |
|---|---|---|---|---|---|---|---|
| | 15 | 16 | 17 | 18 | 19 | 20 | 21 |
| SiO₂ | 59.5 | 54.5 | 50.5 | 61.5 | 54.5 | 63.0 | 68.0 |
| Al₂O₃ | 0.0 | 0.0 | 0.0 | 0.0 | 0.0 | 0.0 | 0.0 |
| B₂O₃ | 3.0 | 8.0 | 12.0 | 0.0 | 0.0 | 5.0 | 0.0 |
| P₂O₅ | 0.0 | 0.0 | 0.0 | 1.0 | 0.0 | 0.0 | 0.0 |
| GeO₂ | 0.0 | 0.0 | 0.0 | 0.0 | 8.0 | 0.0 | 0.0 |
| MgO | 13.5 | 10.5 | 13.0 | 17.5 | 15.0 | 12.0 | 17.0 |
| CaO | 0.0 | 0.0 | 0.0 | 0.0 | 0.0 | 0.0 | 0.0 |
| SrO | 11.0 | 12.5 | 13.0 | 10.0 | 10.5 | 5.0 | 10.0 |
| BaO | 13.0 | 14.5 | 11.5 | 10.0 | 12.0 | 15.0 | 5.0 |
| Na₂O | 0.0 | 0.0 | 0.0 | 0.0 | 0.0 | 0.0 | 0.0 |
| TiO₂ | 0.0 | 0.0 | 0.0 | 0.0 | 0.0 | 0.0 | 0.0 |
| R²O | 37.5 | 37.5 | 37.5 | 37.5 | 37.5 | 32.0 | 32.0 |
| R¹₂O | 0.0 | 0.0 | 0.0 | 0.0 | 0.0 | 0.0 | 0.0 |
| SrO/BaO | 0.8 | 0.9 | 1.1 | 1.0 | 0.9 | 0.3 | 2.0 |
| Etching rate | 270 | 306 | 325 | 266 | 293 | 403 | 404 |
| [nm/h] | | | | | | | |
| Number of | 38 | 44 | 36 | 39 | 39 | 37 | 43 |
| particles | | | | | | | |
| Particle | A | A | A | A | A | A | A |
| composition | | | | | | | |

TABLE 4

| | Example | Example | Example | Example | Example | Example | Example | Example |
|---|---|---|---|---|---|---|---|---|
| | 22 | 23 | 24 | 25 | 26 | 27 | 28 | 29 |
| SiO₂ | 60.0 | 100.0 | 44.7 | 42.5 | 43.6 | 59.0 | 63.0 | 75.0 |
| Al₂O₃ | 15.0 | 0.0 | 0.0 | 0.0 | 0.0 | 0.0 | 0.0 | 0.0 |
| B₂O₃ | 0.0 | 0.0 | 0.0 | 0.0 | 0.0 | 0.0 | 0.0 | 7.0 |
| P₂O₅ | 0.0 | 0.0 | 0.0 | 0.0 | 0.0 | 0.0 | 0.0 | 0.0 |
| GeO₂ | 0.0 | 0.0 | 0.0 | 0.0 | 0.0 | 0.0 | 0.0 | 0.0 |
| MgO | 9.0 | 0.0 | 26.6 | 7.0 | 17.1 | 13.0 | 11.0 | 5.0 |
| CaO | 0.0 | 0.0 | 28.7 | 50.5 | 39.3 | 0.0 | 0.0 | 0.0 |
| SrO | 9.0 | 0.0 | 0.0 | 0.0 | 0.0 | 13.0 | 11.0 | 5.0 |
| BaO | 7.0 | 0.0 | 0.0 | 0.0 | 0.0 | 15.0 | 15.0 | 8.0 |
| Na₂O | 0.0 | 0.0 | 0.0 | 0.0 | 0.0 | 5.0 | 0.0 | 0.0 |
| TiO₂ | 0.0 | 0.0 | 0.0 | 0.0 | 0.0 | 0.0 | 5.0 | 0.0 |
| R²O | 25.0 | 0.0 | 55.3 | 57.5 | 56.4 | 41.0 | 37.0 | 18.0 |
| R¹₂O | 0.0 | 0.0 | 0.0 | 0.0 | 0.0 | 5.0 | 0.0 | 0.0 |
| SrO/BaO | 1.3 | — | — | — | — | 0.9 | 0.7 | 0.6 |
| Etching rate | 686 | 3530 | 131 | 77 | 108 | 263 | 308 | 1066 |
| [nm/h] | | | | | | | | |
| Number of | 36 | 42 | 110 | 167 | 141 | 36 | 44 | 43 |
| particles | | | | | | | | |
| Particle | B | A | A | A | A | C | C | A |
| composition | | | | | | | | |

### <Conclusion of Evaluation Results>

As shown in the above tables, in the glass blocks in Examples 1 to 22, the etching rate obtained by the etching resistance test is 700 nm/h or less, and the etching resistance under a plasma environment is excellent. In addition, as a result of the dust generation test, in Examples 1 to 22, the number of particles generated by the plasma etching is as small as 50 or less, and the dust generation resistance is excellent. In addition, since the precipitated particles contain neither the alkali metal element nor Ti that may greatly influence the performance of the semiconductor product, it is shown that the glass blocks in Examples 1 to 22 are composed of components that do not cause any problem even when the particles are precipitated in the semiconductor production apparatus, and are suitable as the member for a semiconductor production apparatus.

In contrast, in the glass block in Example 23 produced using a quartz glass containing no alkaline earth metal element as a raw material, the etching rate is higher than 3,500 nm/h as a result of the etching resistance test, and it is shown that the glass block is not suitable as the member for a semiconductor production apparatus.

In addition, in Examples 24 to 26, the etching rate is good, but the number of particles is more than 100 as a result of the dust generation test, and it is shown that the glass blocks are not suitable as the member for a semiconductor production apparatus. It is presumed that this is because the glass blocks in Examples 24 to 26 contain a large amount of Ca. The FIGURE is a graph showing a relationship between a Ca content (in mol % based on oxides, horizontal axis) in the glass block and the number of particles having a diameter of 100 nm or more (vertical axis) measured after the dust generation test in each example. It is understood from the FIGURE that as the Ca content in the glass block increases, the number of particles tends to increase and the dust generation resistance tends to decrease.

In Examples 27 and 28, the evaluation of the particle composition obtained in the dust generation test is “C”, and it is shown that the glass blocks are not suitable as the member for a semiconductor production apparatus. Since the glass block in Example 27 contains Na as an alkali metal element and the glass block in Example 28 contains Ti, it is presumed that the particles containing a component that may greatly influence the performance of the semiconductor product are generated by the plasma etching.

In Example 29, as a result of the etching resistance test, the etching rate is higher than 1,000 nm/h, and it is shown that the glass block is not suitable as the member for a semiconductor production apparatus. It is presumed that this is because the content of the alkaline earth metal in Example 29 is small.

The present application is based on Japanese Patent Applications No. 2024-146419 filed on Aug. 28, 2024 and No. 2025-135599 filed on Aug. 18, 2025, and the contents thereof are incorporated herein by reference.

What is claimed is:

1. A glass comprising:
silicon;
magnesium;
strontium; and
barium, wherein
the glass has, in mol % based on oxides, a content of SiO₂ of 48.0 mol % or more, a content of Al₂O₃ of 20.0 mol % or less, a content of MgO of 0.1 mol % or more, a content of SrO of 0.1 mol % or more, a content of BaO of 0.1 mol % or more, and a content of R²O of 22.0 mol % or more, provided that R² indicates an alkaline earth metal element, and
the glass is substantially free of CaO, substantially free of TiO₂, and substantially free of R¹₂O, provided that R¹ indicates an alkali metal element.

2. The glass according to claim 1, wherein the content of Al₂O₃ is 13.5 mol % or less.

3. The glass according to claim 1, which is substantially free of Al₂O₃.

4. The glass according to claim 1, wherein the content of BaO is 4.0 mol % to 14.0 mol %.

5. The glass according to claim 1, wherein
the content of Al₂O₃ is 13.5 mol % or less, and
the content of BaO is 4.0 mol % to 14.0 mol %.

6. The glass according to claim 1, which is a glass block.

7. The glass according to claim 1, which is a disk-shaped glass block.

8. The glass according to claim 1, which is an annular glass block.

9. The glass according to claim 1, which is for use as a member for a semiconductor production apparatus to be mounted on a semiconductor production apparatus.

10. The glass according to claim 9, wherein the member for a semiconductor production apparatus is an edge ring, a shield ring, a focus ring, a shower plate, an electrostatic chuck, a susceptor, an injector, an inspection window, a top plate, or a side wall to be mounted on the semiconductor production apparatus.

11. A method for producing the glass according to claim 1, the method comprising:
melting a glass raw material by heating at a melting temperature of 1,400° C. to 1,800° C.; and
cooling the obtained molten glass to a cooling stop temperature of 500° C. to 700° C. at a cooling rate of 100° C./min to 1,500° C./min.

12. A member for a semiconductor production apparatus comprising:
the glass according to claim 1.

13. The member for a semiconductor production apparatus according to claim 12, which is an edge ring, a shield ring, a focus ring, a shower plate, an electrostatic chuck, a susceptor, an injector, an inspection window, a top plate, or a side wall to be mounted on a semiconductor production apparatus.

14. A semiconductor production apparatus comprising:
the member for a semiconductor production apparatus according to claim 12.

15. A semiconductor production apparatus comprising:
the member for a semiconductor production apparatus according to claim 13.
